(19) United States
(12) Patent Application Publication
(10) Pub. No.: US 2023/0274919 A1
(43) Pub. Date: Aug. 31, 2023

(54) CONTROLLING TEMPERATURE PROFILES OF PLASMA CHAMBER COMPONENTS USING STRESS ANALYSIS

(71) Applicant: LAM RESEARCH CORPORATION, Fremont, CA (US)

(72) Inventor: John DREWERY, San Jose, CA (US)

(21) Appl. No.: 18/013,475

(22) PCT Filed: Aug. 11, 2021
(86) PCT No.: PCT/US2021/045471

§ 371 Date: Dec. 28, 2022

Related U.S. Application Data
(60) Provisional application No. 63/067,115, filed on Aug. 18, 2020.

(51) Int. Cl. H01J 37/32

(52) U.S. Cl. CPC H01J 37/3299; H01J 37/32522; H01J 37/32724; H01J 37/32935

(57) ABSTRACT

A system for estimating stress on a component of a processing chamber during a process includes a plurality of sensors configured to sense temperatures at a plurality of locations of the component during the process and a controller a controller configured to interpolate the temperatures to estimate a temperature distribution across the component and to estimate the stress on the component during the process. A method of estimating stress on a component of a processing chamber during a process includes sensing temperatures at a plurality of locations of the component during the process, interpolating the temperatures to estimate a temperature distribution across the component, and estimating the stress on the component during the process.

### CROSS-REFERENCE TO RELATED APPLICATIONS

This application claims the benefit of U.S. Provisional Application No. 63/067,115, filed on Aug. 18, 2020. The entire disclosure of the application referenced above is incorporated herein by reference.

### FIELD

The present disclosure relates generally to substrate processing systems and more particularly to controlling temperature profiles of plasma chamber components using stress analysis.

### BACKGROUND

The background description provided here is for the purpose of generally presenting the context of the disclosure. Work of the presently named inventor, to the extent it is described in this background section, as well as aspects of the description that may not otherwise qualify as prior art at the time of filing, are neither expressly nor impliedly admitted as prior art against the present disclosure.

A substrate processing system typically includes a plurality of processing chambers (also called process modules) to perform deposition, etching, and other treatments of substrates such as semiconductor wafers. Examples of processes that may be performed on a substrate include, but are not limited to, plasma enhanced chemical vapor deposition (PECVD), chemically enhanced plasma vapor deposition (CEPVD), sputtering physical vapor deposition (PVD), atomic layer deposition (ALD), and plasma enhanced ALD (PEALD). Additional examples of processes that may be performed on a substrate include, but are not limited to, etching (e.g., chemical etching, plasma etching, reactive ion etching, etc.) and cleaning processes.

During processing, a substrate is arranged on a substrate support assembly such as a pedestal or an electrostatic chuck (ESC) arranged in a processing chamber of the substrate processing system. A robot typically transfers substrates from one processing chamber to another in a sequence in which the substrates are to be processed. During deposition, gas mixtures including one or more precursors are introduced into the processing chamber, and plasma is struck to activate chemical reactions. During etching, gas mixtures including etch gases are introduced into the processing chamber, and plasma is struck to activate chemical reactions. The processing chambers are periodically cleaned by supplying a cleaning gas into the processing chamber and striking plasma.

### SUMMARY

A system for estimating stress on a component of a processing chamber during a process comprises a plurality of sensors configured to sense temperatures at a plurality of locations of the component during the process and a controller a controller configured to interpolate the temperatures to estimate a temperature distribution across the component and to estimate the stress on the component during the process.

In another feature, the controller is further configured to control a parameter of the process to limit the stress on the component during the process.

In another feature, the controller is further configured to compare the stress to a predetermined value and to indicate when the stress is greater than or equal to the predetermined value.

In another feature, the controller is configured to estimate the stress at one or more locations on the component as a function of positions of the locations on the component.

In another feature, the controller is configured to estimate the temperature distribution based on the temperatures using a model of heat inputs to the component.

In another feature, the controller is configured to estimate the temperature distribution using curve fitting.

In another feature, the controller is configured to estimate the temperature distribution by dividing the component into a plurality of heat zones based on respective heat loads and using curve fitting with the heat loads as fitting parameters.

In another feature, the component is subjected to heating and cooling during the process and is divisible into a plurality of heat zones based on respective heat loads of the heat zones, and the controller is configured to estimate the temperature distribution using curve fitting with the heat loads as fitting parameters.

In another feature, a number of the heat zones is a function of a number of sources of heating and cooling.

In another feature, a number of the sensors is proportional to a number of heat zones.

In other features, the component is axisymmetric, the sensors are arranged on a half portion of the component, and the controller is configured to estimate the stress on the entire component using the sensors arranged on the half portion of the component.

In another feature, the controller is configured to estimate the stress using a matrix with dimension determined based on a number of the sensors.

In other features, the component is a dielectric window of the processing chamber, and the system further comprises a coil arranged on the dielectric window to generate plasma in the processing chamber, and a plenum arranged on the dielectric window to flow a coolant.

In another feature, the controller is configured to estimate the stress at one or more locations on the dielectric window as a function of radius of the dielectric window.

In another feature, the stress includes at least one of a radial stress and a tangential stress.

In other features, the system further comprises a coil driving circuit configure to driver the coil, and a fluid delivery system configured to supply the coolant to the plenum; and the controller is configured to control at least one of the coil driving circuit and the fluid delivery system to limit the stress on the component during the process.

In other features, the controller is configured to divide the component into a plurality of heat zones based on respective heat loads and to determine the following once: a first matrix based on the temperatures, a second matrix based on a decomposition of the first matrix, and a third matrix based on preset positions on the component at which to estimate the stress. The controller is configured to periodically repeat the following during the process: measure a temperature of each of the heat zones using the sensors, determine a fourth matrix for the heat loads using the second matrix, calculate stress integrals based on the third and fourth matrices, and determine whether to limit the stress on the component at any of the preset positions based on a ratio of the calculated stress to a reference stress.

In still other features, a method of estimating stress on a component of a processing chamber during a process comprises sensing temperatures at a plurality of locations of the component during the process, interpolating the temperatures to estimate a temperature distribution across the component, and estimating the stress on the component during the process.

In another feature, the method further comprises controlling a parameter of the process to limit the stress on the component during the process.

In another feature, the method further comprises comparing the stress to a predetermined value, and indicating when the stress is greater than or equal to the predetermined value.

In another feature, the method further comprises estimating the stress at one or more locations on the component as a function of positions of the locations on the component.

In another feature, the method further comprises estimating the temperature distribution based on the temperatures using a model of heat inputs to the component.

In another feature, the method further comprises estimating the temperature distribution using curve fitting.

In another feature, the method further comprises estimating the temperature distribution by dividing the component into a plurality of heat zones based on respective heat loads and using curve fitting with the heat loads as fitting parameters.

In other features, the component is subjected to heating and cooling during the process, and the method further comprises dividing the component into a plurality of heat zones based on respective heat loads of the heat zones, and estimating the temperature distribution using curve fitting with the heat loads as fitting parameters.

In another feature, the method further comprises selecting a number of the heat zones as a function of a number of sources of heating and cooling.

In another feature, the method further comprises selecting a number of sensors for sensing the temperatures proportional to a number of heat zones.

In other features, the component is axisymmetric, and the method further comprises arranging sensors for sensing the temperatures on a half portion of the component, and estimating the stress on the entire component using the sensors arranged on the half portion of the component.

In another feature, the method further comprises estimating the stress using a matrix with dimension determined based on a number of sensors used for sensing the temperatures.

In other features, the component is a dielectric window of the processing chamber, and the method further comprises arranging a coil on the dielectric window to generate plasma in the processing chamber, and arranging a plenum on the dielectric window to flow a coolant.

In another feature, the method further comprises estimating the stress at one or more locations on the dielectric window as a function of radius of the dielectric window.

In another feature, the stress includes at least one of a radial stress and a tangential stress.

In another feature, the method further comprises controlling at least one of a power supply to the coil and supply of the coolant to the plenum to limit the stress on the component during the process.

In other features, the method further comprises dividing the component into a plurality of heat zones based on respective heat loads and determining the following once: a first matrix based on the temperatures, a second matrix based on a decomposition of the first matrix, and a third matrix based on preset positions on the component at which to estimate the stress. The method further comprises periodically repeating the following during the process: measuring a temperature of each of the heat zones, determining a fourth matrix for the heat loads using the second matrix, calculating stress integrals based on the third and fourth matrices, and determining whether to limit the stress on the component at any of the preset positions based on a ratio of the calculated stress to a reference stress.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a substrate processing system according to the present disclosure;

FIG. 2 shows a system for controlling stress on a component of a processing chamber such as a dielectric window;

FIG. 3 shows a system for controlling stress on a component of a processing chamber such as a dielectric window according to the present disclosure;

FIGS. 4A-4C show a method of controlling stress on a component of a processing chamber such as a dielectric window according to the present disclosure; and

FIG. 5 shows an example of implementing the method of FIGS. 4A-4C according to the present disclosure.

In the drawings, reference numbers may be reused to identify similar and/or identical elements.

### DETAILED DESCRIPTION

Thermal stress due to non-uniform heating can cause damage to brittle components in processing chambers. For example, in conductor etch processing chambers, a dielectric window is susceptible to damage due to thermal stress caused by non-uniform heating. Non-uniform heating occurs in these processing chambers because heat inputs such as charged particle impingement and chemical reaction energy are distributed unevenly in the processing chambers. Cooling employed in the processing chambers is also non-uniform.

Components such as the dielectric window are usually protected by temperature measurement devices. For example, using some combination of temperatures sensed by the temperature measurement devices, a system controller controlling processing chambers may shut down a process being performed in the process module. However, the component generally does not break due to temperature or temperature gradient but due to the stresses caused by these gradients.

The present disclosure provides systems and methods for controlling stress in components such as the dielectric window. Throughout the present disclosure, the dielectric window is used only as an illustrative example of a component that is susceptible to damage due to stress to describe the systems and methods for controlling the stress. The systems and methods can be used to control the stress in any component of a substrate processing system that is subject to similar stresses.

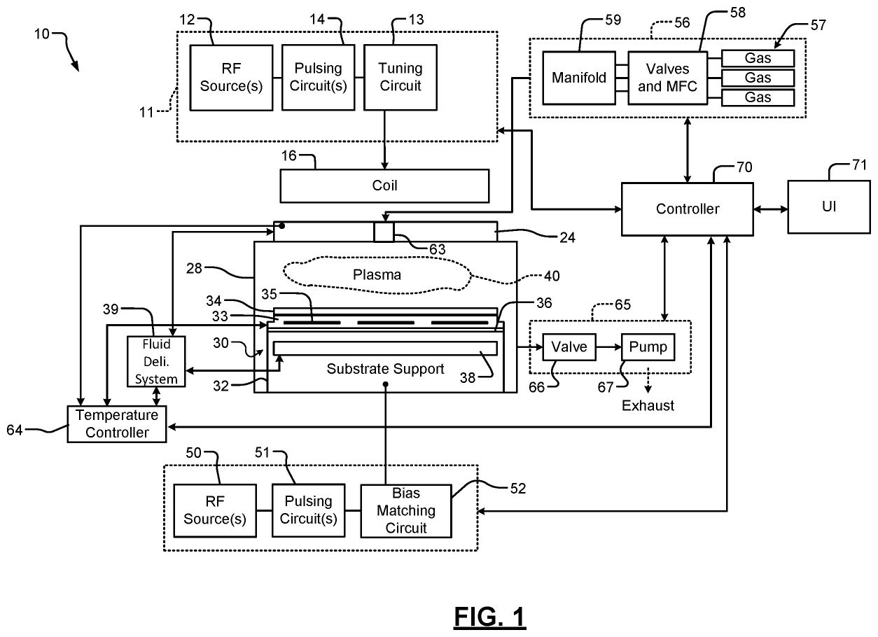

For example, as shown in FIGS. 1-3, which are described below in detail, a dielectric window is a flat annulus with thickness much smaller than its diameter. The dielectric window is supported only at its outer edge (circumference), which makes the dielectric window susceptible to analytical calculations of its stress state. While these calculations lead to a convenient and simple solution in case of the dielectric window, the methods below are in principle applicable to any component, regardless of its geometry, composition, size and shape, and mounting in substrate processing systems.

A system according to the present disclosure calculates an approximate stress state of the dielectric window using information provided by a limited number of temperature sensors. A model of heat inputs to the dielectric window is used in conjunction with the sensor data to provide an estimate of a temperature distribution across the dielectric window, which is then used to calculate the stress using a computationally inexpensive method. Using a computationally inexpensive method allows frequent updating of the stress state in near real time so that the system controller can, in a timely manner, modify the heat inputs to the dielectric window by changing process set points or by shutting down the process. A benefit of this method is that it leads to limitation of the stress itself. These and other features of the present disclosure are described below in detail.

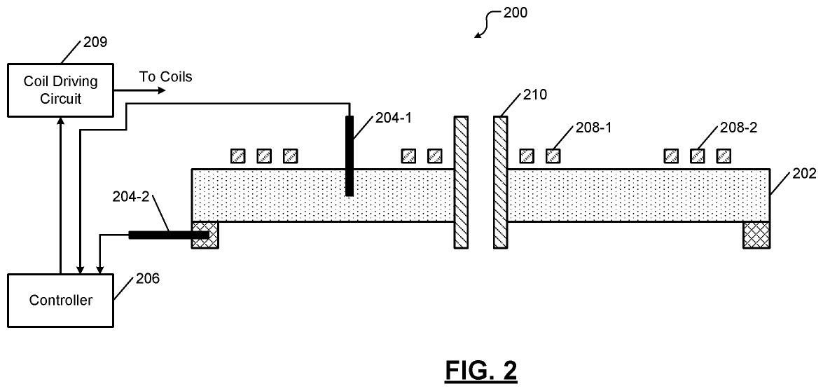

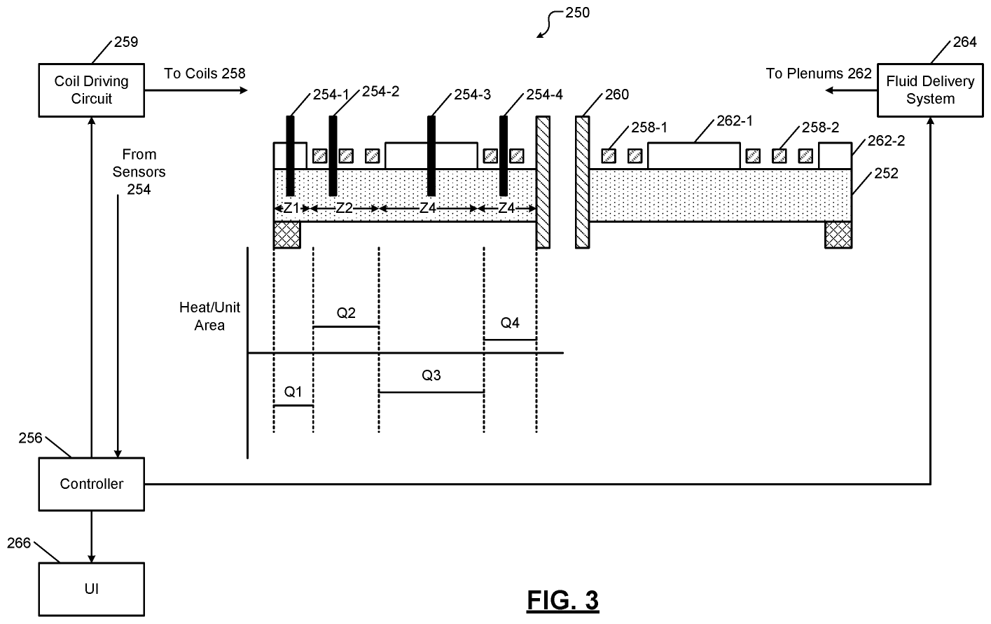

The present disclosure is organized as follows. Initially, an example of a substrate processing system in which the system and method of the present disclosure can be used is shown and described with reference to FIG. 1. Thereafter, using the dielectric window as an example, a method of controlling stress is explained with reference to FIG. 2. Subsequently, an example of a system and a method for controlling stress according to the present disclosure are shown and described with reference to FIGS. 3-5.

FIG. 1 shows an example of a substrate processing system 10 that uses inductively coupled plasma to etch substrates such as semiconductor wafers according to the present disclosure. The substrate processing system 10 includes a coil driving circuit 11. In some examples, the coil driving circuit 11 includes an RF source 12, a pulsing circuit 14, and a tuning circuit (i.e., matching circuit) 13. The pulsing circuit 14 controls a transformer coupled plasma (TCP) envelope of an RF signal generated by the RF source 12 and varies a duty cycle of TCP envelope between 1% and 99% during operation. The pulsing circuit 14 and the RF source 12 can be combined or separate.

The tuning circuit 13 may be directly connected to an inductive coil 16. While the substrate processing system 10 uses a single coil, some substrate processing systems may use a plurality of coils (e.g., inner and outer coils). The tuning circuit 13 tunes an output of the RF source 12 to a desired frequency and/or a desired phase, and matches an impedance of the inductive coil 16.

A dielectric window 24 is arranged along a top side of a processing chamber 28. The processing chamber 28 comprises a substrate support (or pedestal) 30 to support a substrate 34. The substrate support 30 may include an electrostatic chuck (ESC), or a mechanical chuck or other type of chuck. The substrate support 30 comprises a baseplate 32. A ceramic plate 33 is arranged on a top surface of the baseplate 32. A thermal resistance layer 36 may be arranged between the ceramic plate 33 and the baseplate 32. The substrate 34 is arranged on the ceramic plate 33 during processing. A plurality of heaters 35 is arranged in the ceramic plate 33 to heat the substrate 34 during processing. For example, the heaters 35 comprise printed traces embedded in the ceramic plate 33.

The baseplate 32 further includes a cooling system 38 to cool the substrate support 30. The cooling system 38 uses a fluid supplied by a fluid delivery system 39 to cool the substrate support 30. In addition, the fluid delivery system 39 can supply fluid to manifolds (see FIG. 3) arranged on the dielectric window 24 to cool portions of the dielectric window 24 as shown and described below with reference to FIG. 3.

A process gas is supplied to the processing chamber 28, and plasma 40 is generated inside of the processing chamber 28 by supplying RF power to the inductive coil 16. The plasma 40 etches an exposed surface of the substrate 34. An RF source 50, a pulsing circuit 51, and a bias matching circuit 52 may be used to bias the substrate support 30 during processing to control ion energy.

A gas delivery system 56 may be used to supply a process gas mixture to the processing chamber 28. The gas delivery system 56 may include process and inert gas sources 57, a gas metering system 58 such as valves and mass flow controllers, and a manifold 59. A gas injector 63 may be arranged at a center of the dielectric window 24 and is used to inject gas mixtures from the gas delivery system 56 into the processing chamber 28. Additionally or alternatively, the gas mixtures may be injected from the side of the processing chamber 28.

A temperature controller 64 may be connected to the heaters 35 and may be used to control the heaters 35 to control a temperature of the substrate support 30 and the substrate 34. The temperature controller 64 may communicate with the fluid delivery system 39 to control fluid flow through the cooling system 38 to cool the substrate support 30. In addition, the temperature controller 64 may control fluid flow though the manifolds arranged over the dielectric window 24 as explained below with reference to FIG. 3. The dielectric window 24 may include a plurality of temperature sensors as shown and described below with reference to FIG. 3 to sense temperatures in a plurality of zones of the dielectric window 24. The temperature controller 64 may control the fluid flow through the manifolds and may control the etching process being performed in the processing chamber 28 based on feedback from the temperature sensors as described below with reference to FIG. 3.

An exhaust system 65 includes a valve 66 and pump 67 to control pressure in the processing chamber 28 and/or to remove reactants from the processing chamber 28 by purging or evacuation. A controller 70 (also called system controller) may be used to control the etching process. The controller 70 controls the components of the substrate processing system 10. The controller 70 monitors system parameters and controls delivery of the gas mixture; striking, maintaining, and extinguishing the plasma;

removal of reactants; supply of cooling fluid; and so on. Additionally, the controller 70 may control various aspects of the coil driving circuit 11, the RF source 50, and the bias matching circuit 52, and so on. A user interface (UI) 71 allows operators to interact with the substrate processing system 10 via the controller 70.

FIG. 2 shows an example of a system 200 for controlling stress on a component such as a dielectric window. The system 200 comprises a dielectric window 202 (e.g., element 24 shown in FIG. 1) and temperature sensors 204-1 and 204-2 (collectively temperature sensors 204). A controller 206 (e.g., elements 64, 70 shown in FIG. 1) monitors the temperature of the dielectric window 202 based on inputs received from the temperature sensors 204.

Inner and outer coils 208-1, 208-2 (collectively coils 208, similar to element 16 shown in FIG. 1) are arranged on the dielectric window 202. A coil driving circuit 209 (similar to element 11 shown in FIG. 1) drives the coils 208. A gas injector 210 (similar to element 63 shown in FIG. 1) is arranged at a center of the dielectric window 202 and is used to inject gas mixtures into a processing chamber (e.g., element 28 shown in FIG. 1).

To control stress on the dielectric window 202, the temperature of the temperature sensor 204-1 is not allowed to rise above a first predetermined threshold. Further, if the difference between temperatures sensed by the temperature sensors 204-1 and 204-2 exceeds a second predetermined threshold, the controller 206 stops the process being performed in the processing chamber. The system 200 provides an elementary level of stress control for the dielectric window 202 and provides inadequate protection in many practical cases.

In another method, stress control can also be performed by limiting process recipes on a heuristic basis. This method involves selecting stress-generating processes and running them with a dielectric window fitted with a relatively large array of temperature sensors. A stress state of the dielectric window is calculated based on data collected from the array of temperature sensors. By running many tests, rules can be derived that can be applied to limit the process settings. However, this method is laborious since the tool has many settable process variables for different processes.

Instead, according to the method of the present disclosure, use of direct stress calculations allows the dielectric window to be protected from damage for any set of process variables in near real time. Generally, using at least three temperature sensors can provide a sufficiently accurate stress estimation under the assumption of radial symmetry of the dielectric window. Additional sensors may be used if azimuthal variation of the temperature is to be considered.

FIG. 3 shows a system 250 for controlling stress on a component such as a dielectric window according to the present disclosure. The system 250 comprises a dielectric window 252 (e.g., element 24 shown in FIG. 1) and temperature sensors 254-1, 254-2, 254-3, and 254-4 (collectively temperature sensors 254). While four temperature sensors 254 are shown, three temperature sensors 254 are sufficient.

The dielectric window 252 is divided into a plurality of radial heat zones (e.g., four heat zones shown as Z1, Z2, Z3, and Z4). For example, the heat zones may be generally based on the arrangements of coils and plenums (elements 258 and 262 described below) above the dielectric window 252, which respectively cause heating and cooling of the dielectric window 252.

The temperatures sensed by the temperature sensors 254 represent the temperatures of the respective heat zones of the dielectric window 252. While four heat zones and four temperature sensors 254 are shown for illustrative purposes, a one-to-one correspondence between the heat zones and the temperature sensors 254 is not necessary. For example, the number of temperature sensors 254 can be less or greater than the number of heat zones.

A controller 256 (e.g., elements 64, 70 shown in FIG. 1) monitors the temperature of the dielectric window 252 based on inputs received from the temperature sensors 254. Inner and outer coils 258-1, 258-2 (collectively coils 258, similar to element 16 shown in FIG. 1) are arranged on the dielectric window 252. A coil driving circuit 259 (similar to element 11 shown in FIG. 1) drives the coils 258. The controller 256 controls the coil driving circuit 259 to control the power supplied to the coils 258 based on the inputs from the temperature sensors 254. A gas injector 260 (similar to element 63 shown in FIG. 1) is arranged at the center of the dielectric window 252 and is used to inject gas mixtures into a processing chamber (e.g., element 28 shown in FIG. 1).

One or more plenums 262-1, 262-2 (collectively plenums 262) are arranged on the dielectric window 252 as shown. A fluid delivery system 264 (e.g., element 39 shown in FIG. 1) flows a coolant through the plenums 262 to cool the dielectric window 252. The controller 256 controls the fluid delivery system 264 to control the fluid flow through the plenums 262 based on inputs from the temperature sensors 254.

The number of heat zones is not a function of the number of coils 258 and plenums 262. For example, while not shown, multiple heat zones can be used even if a single coil is arranged on the dielectric window 252. The heat zones can be selected so as to obtain the best fit (as empirically determined) to the temperature for a wide rang of processes. The selection of the heat zones can be but is not necessarily related to the cooling/heating layout. The controller 256 provides stress indications on a user interface (UI) 266 (e.g., element 71 shown in FIG. 1), which allows operators to operate elements of the substrate processing system (e.g., element 10 shown in FIG. 1) via the controller 256 based on the stress indications.

The cost and engineering complexity limit the number of temperature sensors 254 that may be used to measure the temperature distribution in the dielectric window 252. To use this limited data, the controller 256 interpolates the data received from the temperature sensors 254 that can be used directly or indirectly to estimate the stress on the dielectric window 252.

Specifically, as explained below in detail, the controller 256 provides a fit for the temperature distribution across the dielectric window 252 as a function of the radius of the dielectric window 252 based on the measurements from the limited number of temperature sensors 254. Using the fit function, the controller 256 determines the stress state of the window using a simple integration.

In use, the controller 256 implements this method by performing a one-time matrix calculation that depends only on a physical layout of the dielectric window 252, followed by simple matrix operations to calculate the stress on the dielectric window 252, which can be repeated periodically. Thus, the controller 256 can calculate the stress state of the dielectric window 252 at short intervals (i.e., in near real time) with minimal computational effort.

Briefly, the controller 256 estimates the stress on the dielectric window 252 as follows. The temperature sensors 254 sense the temperatures at multiple locations on the dielectric window 252. The controller 256 interpolates the temperatures using curve fitting as explained below in detail. The controller 256 uses the interpolated temperatures in conjunction with a model that estimates a spatial temperature distribution across the dielectric window 252, and calculates the stress (e.g., compressive or tensile stress) on the dielectric window 252 as a function of radial position of the dielectric window 252. The controller 256 compares the calculated stress to a reference stress, and generates parameters based on the comparison. The controller 256 controls one or more elements of the process (e.g., heating, cooling, power to the coils, etc.) based on the parameters to limit the stress on the dielectric window 252.

The controller 256 can interpolate the temperatures sensed by the temperature sensors 254 as follows. The controller 256 can use various options for fitting the measured temperatures of the dielectric window 252 to an underlying temperature distribution across the dielectric window 252. These options fall into two categories. A first category includes curve-fitting methods that do not assume an underlying heating pattern. Examples of these methods include spline and polynomial fits that interpolate a curve through measurement points. Since these methods do not incorporate additional knowledge of the underlying heating process, the fits provided by these methods are simple smooth curves that may pass through the measurement data points and the fitting process adds nothing other than interpolating the data.

A second category includes methods that assume some heat load distributions. If properties of heat inputs and outputs to and from the dielectric window 252 are known, these methods can be used to improve the temperature estimates across the dielectric window 252. In one example, the temperature estimates are based on the assumption that the heat load is constant in a piecewise manner (i.e., in the zones of the dielectric window 252) as shown in FIG. 3. This assumption may be justified if the controller 254 can control cooling applied through the plenums 262 in the radial zones at a relatively constant heat removal rate per unit area, and heating is either relatively uniform or constant across these zones. In practice, this assumption yields a much better fit to measured temperature distributions than the simple curve fits provided by the methods of the first category.

The heat loads Q1-Q4 of the multiple zones are the fitting parameters. The fitted parameters can be compared with actual estimates of these heat loads to improve confidence in the fit. The locations of the temperature sensors 254 can be optimized to provide the best estimate of the underlying temperature profile of the dielectric window 252 over a large range of processes.

The controller 256 uses a model that estimates a spatial stress distribution 25 across the dielectric window 252 to calculate the stress (e.g., compressive or tensile stress) on the dielectric window 252. The model is based on heat inputs to the dielectric window 252. The controller 256 can calculate the stress distribution based on plane strain or plane stress analysis performed using any of the following methods.

For example, in a first method, numerical integration of an analytical formula for the stress is performed. Specifically, t the stress calculation can be reduced to a polynomial form by piecewise integration. This allows a radial stress calculation to be performed at any radius of the dielectric window 252 by using matrix calculations involving a matrix with dimension approximately the same as the number of the temperature sensors 254. This method has a relatively low computational load since the controller 256 does not need to perform the integration, which is one reason why the radial stress calculation is fast. Accordingly, the controller 254 can perform the radial stress calculation many times during a process and can limit the stress on the dielectric window 252 in near real time.

In a second method, the controller 256 can calculate the stress distribution across the dielectric window 252 using a two-dimensional finite-element calculation. In a third method, the controller 256 can use a multidimensional lookup table of empirically pre-calculated stress distributions indexed by a suitable binning of the temperature measurements across the dielectric window 252.

Following the estimation of the stress state of the dielectric window 252, the controller 256 estimates parameters for limiting the stress on the dielectric window 252. For example, the controller 256 can generate a ratio of the calculated stress to a reference stress. The ratio can indicate whether the dielectric window 252 may be damaged. The reference stress may be different depending on whether the calculated stress is compressive or tensile (ceramic materials fail under much lower stresses when in tension), or may depend on the position of the component such as the dielectric window 252 (e.g., the component may include a feature that strengthens or weakens the component locally).

Based on the parameters for limiting the stress, the controller 256 can respond in many different ways. For example, if the parameters indicate a hazardous stress state, a warning or alarm can be provided on the user interface 266, based on which an operator can abort the process. Alternatively, if the parameters indicate a hazardous stress state, the controller 256 can limit the heat loads on the component such as the dielectric window 252 by controlling subsystems that affect heating and/or cooling. For example, the controller 256 can control the coil driving circuit 259 to control the power supplied to the coils 258 and/or the fluid delivery system 264 to control the coolant flow through the plenums 262.

The method of performing a thermal analysis of the dielectric window 252 is now explained in further detail. As described with reference to FIG. 1, The RF power supplied to the coils 258 causes a plasma to form in a process space under the dielectric window 252 (e.g., plasma 40 is formed in the processing chamber 28 in FIG. 1), which causes heating of the dielectric window 252. For the purposes of thermal analysis, the dielectric window 252 can be thought of as a thin plate with thickness significantly less than the diameter. In the Example shown in FIG. 3, four temperature sensors 254 are embedded in the dielectric window 252. For the purposes of curve fitting, the dielectric window 252 is regarded as having four radial zones as shown, and the fit is carried out by the controller 256 using a model that assumes that there is a relatively constant net heat load per unit area in each zone.

With four temperature sensors 254 and with four heat loads as four fitting parameters, a relationship between a temperature at a radius r of the dielectric window 252 and the heat loads Qⱼ is given by the equation T(r)=ΣAⱼ(r)Qⱼ+Tₒ, where a vector of parameters Aⱼ depends on the geometry, namely the locations of the zone boundaries and the radius at which the temperature is desired. Aⱼ(r) are interpolation functions that depend on the method used to interpolate the temperature. The controller 256 determines the heat loads Qⱼ using temperature values at the locations of the temperature sensors 254 using the equation Tᵢ=T(rᵢ)=ΣAⱼ(rᵢ)Qⱼ+Tₒ, where i, j=1 to 4. An additional constraint that the total power to the dielectric window 252 is zero is used to find the additional parameter To.

Given this fitting curve, the controller 256 can determine the thermal stresses by integration. Since the form of Aᵢⱼ(r) is known, it can be integrated analytically to find another linear equation for each stress component. Due to the axisymmetric structure of the dielectric window 254, there are two principal stress components: a radial component σᵣᵣ and a tangential component σ_{θθ}. The radial component is given by the formula σᵣᵣ(r)=ΣBⱼ(r)Qⱼ+C. The terms in B and the constant C are determined by the integration mentioned above.

Referring to Aⱼ(rᵢ) as Aᵢⱼ, we have Qⱼ=Aᵢⱼ⁻¹(Tᵢ−T₀), so that σᵣᵣ(r)=ΣBⱼ(r)Aᵢⱼ⁻¹(Tᵢ−T₀)+C. The parameter Bⱼ(r)Aᵢⱼ⁻¹ need only be calculated once for each value of r. Evaluation of the stress at any given radius of the dielectric window 252 is then performed in order—in N cycles, where N is the number of zones in the fit. The controller 256 can perform this calculation relatively fast (e.g., in a few microseconds or less).

The controller 256 then receives measurements of the temperatures. The controller 256 uses the above equation to determine the radial component σᵣᵣ of the stress as a function of the radius of the dielectric window 252. The controller 256 evaluates the radial component of the stress at a number of radii of the dielectric window 252 to determine a stress profile of the dielectric window 252. The resolution of the stress profile is such that a maximum stress on the dielectric window 252 can be evaluated to sufficient precision without missing a region of high stress.

The result may be corrected further by adding stresses that are not calculated by the plane-strain calculation used above. For example, the dielectric window 252 is under an atmospheric pressure load during a process. The atmospheric pressure load produces a relatively constant stress on the dielectric window 252 that changes linearly from one surface of the dielectric window 252 to the other. Since the maximum of this stress is on the surface of the dielectric window 252, the stress results can be offset by this additional stress, and two curves can be calculated, one corresponding to each surface of the dielectric window 252.

The results, for both stress components and for both surfaces of the dielectric window 252, are multiplied by a factor to determine a degree to which the stress is a concern for failure of the dielectric window 252. In on example, this factor may be an inverse of the maximum allowable stress on the dielectric window 252. Alternatively, the factor may be different depending on whether the stress is positive or negative corresponding to compressive or tensile stress.

Based on a finite element analysis of the dielectric window 252, supposing that the dielectric window 252 has a weak area at a radius of the dielectric window 252, a further correction may then be applied to raise the concern level at that radius. Finally, the maximum concern value is calculated. Based on this maximum value, the controller 256 may decide to issue a warning on the UI 266, shut off the process power, or limit the process power so as to limit the stress on the dielectric window 252.

Accordingly, the controller 256 provides a fit for the temperature distribution across the dielectric window 252 as a function of the radius of the dielectric window 252 based on the temperature measurements from a limited number of temperature sensors 254 assuming some heat load distributions. Using the fit function, the controller 256 determines the stress state of the window using integration. In practice, the controller 256 implements this method by performing a matrix calculation once that depends only on the physical layout of the dielectric window 252, followed by matrix operations to calculate the stress on the dielectric window 252. Thus, the controller 256 can calculate the stress state of the dielectric window 252 at short intervals (i.e., in near real time) with minimal computational effort. This allows the controller 256 to determine the stress on the dielectric window 252 in near real time during a process, which in turn allows the controller 256 to control process parameters to limit the stress on the dielectric window 252. Since the above method is process-agnostic (i.e., works with any process without any customization specific to a process), the controller 256 can determine and limit the stress on the dielectric window 252 independently of the process.

In one implementation, the controller 256 calculates the temperature and stress matrices once. Using lower-upper (LU) decomposition, the controller 256 generates a version of the temperature matrix once that can then be used to get the Q matrix for any vector of input temperatures. For most components, the controller 256 can calculate the matrix A once for preset radii at which the stress calculation is required.

After these one-time determinations, the controller 256 repeats the following steps periodically: measure one temperature per zone; use the LU decomposed temperature matrix to determine the Q matrix; apply the A matrix to the Q matrix to calculate the stress integrals; and calculate the radial and hoop (tangential) stresses σᵣᵣ and σ_{θθ} from the stress integrals. The controller 256 compares these stresses with safety values (e.g., predetermined thresholds) to assess the danger to the dielectric window 252 and initiates (e.g., alerts an operator) or performs (automatically, without operator intervention) a remedial action based on the assessed danger.

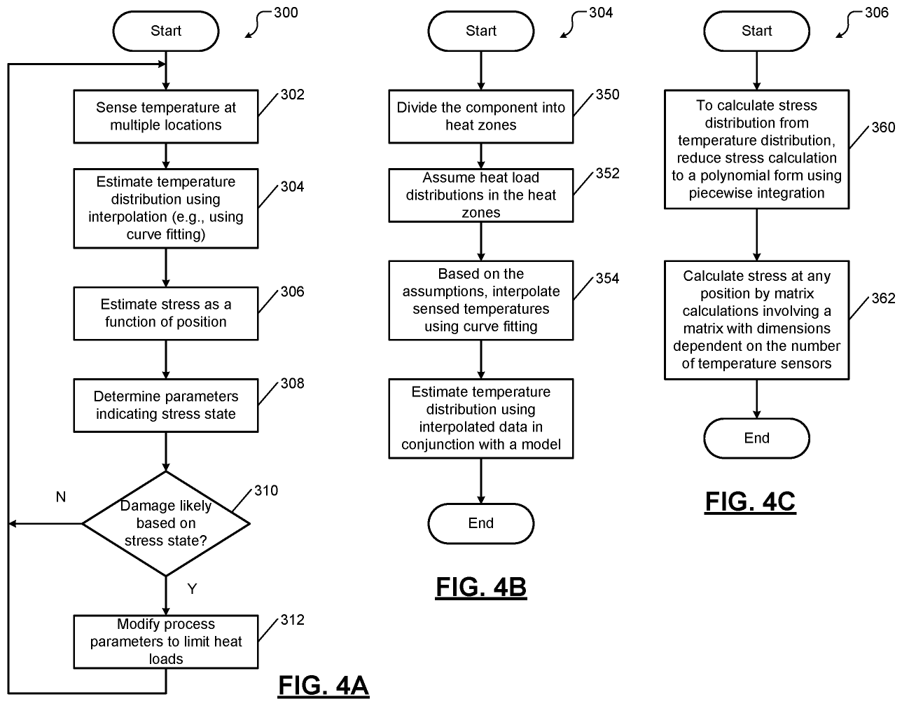

FIGS. 4A-4C show a method 300 for controlling stress on a component such as a dielectric window (e.g., element 252 shown in FIG. 3) according to the present disclosure. FIG. 4A shows the overall method 300 while FIGS. 4B and 4C show some of the steps of the method 300 in further detail as explained below. For example, the controller 256 shown in FIG. 3 can perform the method 300, and the term control in the following description refers to the controller 256 shown in FIG. 3.

In FIG. 4A, at 302, control receives temperatures sensed by temperature sensors (e.g., element 254 shown in FIG. 3) at multiple locations of the component. At 304, control estimates a temperature distribution across the component using interpolation (e.g., using a curve fitting method described above with reference to FIG. 3). Step 304 is shown and described below in further detail with reference to FIG. 4B. At 306, control estimates the stress on the component as a function of position (e.g., as a function of radius of the element 252 shown in FIG. 3). Step 306 is shown and described below in further detail with reference to FIG. 4C.

At 308, control determines parameters (e.g., a ratio of the calculated stress to a reference stress as described above with reference to FIG. 3) indicating a stress state of the component. At 310, control determines if damage is likely to occur to the component based on the stress state. Control returns to 302 if damage is unlikely to occur to the component based on the stress state. At 312, if damage is likely to occur to the component based on the stress state, control modifies (automatically or by alerting an operator) one or more process parameters (e.g., control one or more subsystems such as elements 259, 264 shown in FIG. 3, causing heating and/or cooling of the component), and control returns to 302.

FIG. 4B shows the step 304 of the method 300 in further detail. At 350, control divides the component into heat zones. For example, as explained above with reference to FIG. 3, the heat zones may be designated based on arrangements of heating and cooling sources causing the heating and cooling of the component. At 352, control assumes some heat load distributions in the heat zones. At 354, based on the assumptions of the heat load distributions in the heat zones, control interpolates the sensed temperatures using curve fitting (e.g., using a curve fitting method described above with reference to FIG. 3). At 356, control estimates the temperature distribution across the component using the interpolated and fitted data in conjunction with a model generated based on actual estimate of the heat loads.

FIG. 4C shows the step 306 of the method 300 in further detail. At 360, to calculate stress distribution from the temperature distribution determined in step 304, control reduces the stress calculation to a polynomial form using piecewise integration as explained above with reference to FIG. 3. At 362, control calculates the stress at any position of the component (e.g., at any radius of element 252 shown in FIG. 3) by matrix calculations involving a matrix with dimensions dependent on the number of temperature sensors used. This process is described in detail above with reference to FIG. 3 and is therefore not repeated here for brevity.

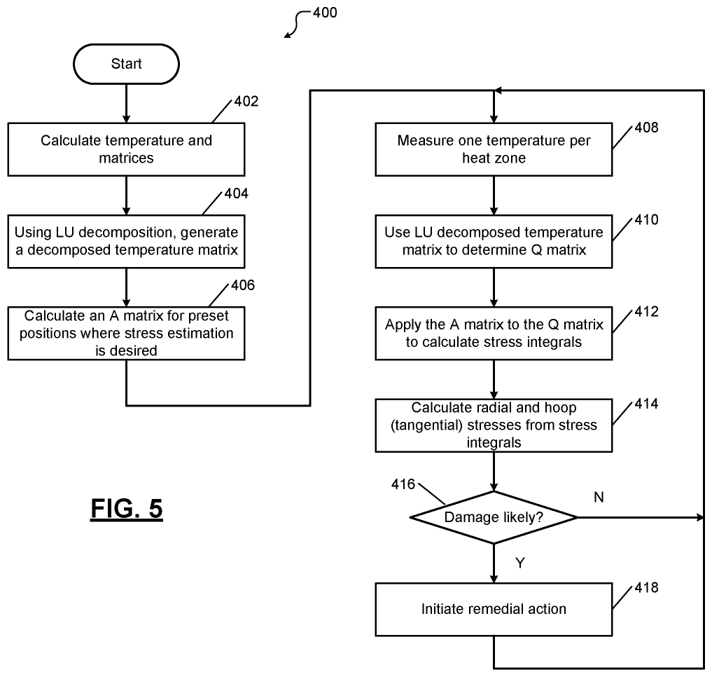

FIG. 5 shows a method 400 for calculating the stress on the component in near real time using the system 250 and the method 300. Essentially, the method 400 shows an example of implementing the method 300. The method 400 illustrates that the computations of the method 300 can be performed relatively fast due to the methods used to estimate the temperature and stress distributions (i.e., interpolation and curve fitting used to estimate the temperature distribution, and the numerical integration used to estimate the stress distribution) described above, so that the stress on the component can be assessed and limited in near real time. For example, the controller 256 shown in FIG. 3 can perform the method 400, and the term control in the following description refers to the controller 256 shown in FIG. 3.

At 402, control calculates temperature and stress matrices. At 404, control generates a decomposed temperature matrix using LU decomposition. At 406, control calculates the A matrix for preset positions (e.g., selected radii of element 252 shown in FIG. 3) where stress estimation is desired. Control performs these steps only once.

That is, control performs these steps only once each time the processing chamber is redesigned or at most when the processing chamber is rebooted (powered on), depending on how the geometric information about the temperature sensors 254 is stored. For example, one can simply store the decomposed matrix, which has only 13 independent elements for a system with four temperature sensors 254.

At 408, control senses temperatures measured by the temperature sensors for each heater zone. At 410, control uses the decomposed temperature matrix from step 404 to determine the Q matrix. At 412, control applies the A matrix from step 406 to the Q matrix to calculate stress integrals. At 414, control calculates radial and hoop (tangential) stresses for the component from the stress integrals.

At 416, control determines based on the radial and hoop stresses whether the component is likely to be damaged. For example, control compares the stresses to safety values or thresholds to determine if the component is in danger to be damaged due to the stresses. Control returns to 408 if the component is unlikely to be damaged by the stresses. At 418, if the component is likely to be damaged by the stresses, control initiates remedial actions, and control returns to 408.

Steps 408 to 414 can be performed relatively fast for the reasons explained above. Therefore, these steps can be repeated periodically or frequently to assess and limit the stress on the component in near real time. Further, as explained above the method 400 is process-agnostic (i.e., can be performed for any process without requiring customization for every process).

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another are within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory. what is claimed is:

1. A system for estimating stress on a component of a processing chamber during a process, the system comprising:
a plurality of sensors configured to sense temperatures at a plurality of locations of the component during the process; and
a controller configured to:
interpolate the temperatures to estimate a temperature distribution across the component; and
estimate the stress on the component during the process.

2. The system of claim 1 wherein the controller is further configured to control a parameter of the process to limit the stress on the component during the process.

3. The system of claim 1 wherein the controller is further configured to:
compare the stress to a predetermined value; and
indicate when the stress is greater than or equal to the predetermined value.

4. The system of claim 1 wherein the controller is configured to estimate the stress at one or more locations on the component as a function of positions of the locations on the component.

5. The system of claim 1 wherein the controller is configured to estimate the temperature distribution based on the temperatures using a model of heat inputs to the component.

6. The system of claim 1 wherein the controller is configured to estimate the temperature distribution using curve fitting.

7. The system of claim 1 wherein the controller is configured to estimate the temperature distribution by dividing the component into a plurality of heat zones based on respective heat loads and using curve fitting with the heat loads as fitting parameters.

8. The system of claim 1 wherein:
the component is subjected to heating and cooling during the process and is divisible into a plurality of heat zones based on respective heat loads of the heat zones; and
the controller is configured to estimate the temperature distribution using curve fitting with the heat loads as fitting parameters.

9. The system of claim 8 wherein a number of the heat zones is a function of a number of sources of heating and cooling.

10. The system of claim 8 wherein a number of the sensors is proportional to a number of heat zones.

11. The system of claim 1 wherein:
the component is axisymmetric;
the sensors are arranged on a half portion of the component; and
the controller is configured to estimate the stress on the entire component using the sensors arranged on the half portion of the component.

12. The system of claim 1 wherein the controller is configured to estimate the stress using a matrix with dimension determined based on a number of the sensors.

13. The system of claim 1 wherein the component is a dielectric window of the processing chamber, the system further comprising:
a coil arranged on the dielectric window to generate plasma in the processing chamber; and
a plenum arranged on the dielectric window to flow a coolant.

14. The system of claim 13 wherein the controller is configured to estimate the stress at one or more locations on the dielectric window as a function of radius of the dielectric window.

15. The system of claim 13 wherein the stress includes at least one of a radial stress and a tangential stress.

16. The system of claim 13 further comprising:
a coil driving circuit configure to driver the coil; and
a fluid delivery system configured to supply the coolant to the plenum,
wherein the controller is configured to control at least one of the coil driving circuit and the fluid delivery system to limit the stress on the component during the process.

17. The system of claim 1 wherein:
the controller is configured to divide the component into a plurality of heat zones based on respective heat loads and to determine once:
a first matrix based on the temperatures;
a second matrix based on a decomposition of the first matrix; and
a third matrix based on preset positions on the component at which to estimate the stress; and
the controller is configured to periodically repeat the following during the process:
measure a temperature of each of the heat zones using the sensors;
determine a fourth matrix for the heat loads using the second matrix;
calculate stress integrals based on the third and fourth matrices; and
determine whether to limit the stress on the component at any of the preset positions based on a ratio of the calculated stress to a reference stress.

18. A method of estimating stress on a component of a processing chamber during a process, the method comprising:
sensing temperatures at a plurality of locations of the component during the process;
interpolating the temperatures to estimate a temperature distribution across the component; and
estimating the stress on the component during the process.

19. The method of claim 18 further comprising controlling a parameter of the process to limit the stress on the component during the process.

20. The method of claim 18 further comprising:
comparing the stress to a predetermined value; and
indicating when the stress is greater than or equal to the predetermined value.

21. The method of claim 18 further comprising estimating the stress at one or more locations on the component as a function of positions of the locations on the component.

22. The method of claim 18 further comprising estimating the temperature distribution based on the temperatures using a model of heat inputs to the component.

23. The method of claim 18 further comprising estimating the temperature distribution using curve fitting.

24. The method of claim 18 further comprising estimating the temperature distribution by dividing the component into a plurality of heat zones based on respective heat loads and using curve fitting with the heat loads as fitting parameters.

25. The method of claim 18 wherein the component is subjected to heating and cooling during the process, the method further comprising:
dividing the component into a plurality of heat zones based on respective heat loads of the heat zones; and
estimating the temperature distribution using curve fitting with the heat loads as fitting parameters.

26. The method of claim 25 further comprising selecting a number of the heat zones as a function of a number of sources of heating and cooling.

27. The method of claim 25 further comprising selecting a number of sensors for sensing the temperatures proportional to a number of heat zones.

28. The method of claim 18 wherein the component is axisymmetric, the method further comprising:
arranging sensors for sensing the temperatures on a half portion of the component; and
estimating the stress on the entire component using the sensors arranged on the half portion of the component.

29. The method of claim 18 further comprising estimating the stress using a matrix with dimension determined based on a number of sensors used for sensing the temperatures.

30. The method of claim 18 wherein the component is a dielectric window of the processing chamber, the method further comprising:
arranging a coil on the dielectric window to generate plasma in the processing chamber; and
arranging a plenum on the dielectric window to flow a coolant.

31. The method of claim 30 further comprising estimating the stress at one or more locations on the dielectric window as a function of radius of the dielectric window.

32. The method of claim 30 wherein the stress includes at least one of a radial stress and a tangential stress.

33. The method of claim 30 further comprising controlling at least one of a power supply to the coil and supply of the coolant to the plenum to limit the stress on the component during the process.

34. The method of claim 28 further comprising:
dividing the component into a plurality of heat zones based on respective heat loads and determining once:
a first matrix based on the temperatures;
a second matrix based on a decomposition of the first matrix; and
a third matrix based on preset positions on the component at which to estimate the stress; and
periodically repeating the following during the process:
measuring a temperature of each of the heat zones;
determining a fourth matrix for the heat loads using the second matrix;
calculating stress integrals based on the third and fourth matrices; and
determining whether to limit the stress on the component at any of the preset positions based on a ratio of the calculated stress to a reference stress.
